(19) United States
(12) Patent Application Publication
(10) Pub. No.: US 2022/0013565 A1
(43) Pub. Date: Jan. 13, 2022

(54) 3D IMAGE SENSOR

(71) Applicant: DB HiTek Co., Ltd., Bucheon-si (KR)

(72) Inventor: Man-Lyun HA, Mungyeong-si (KR)

(21) Appl. No.: 17/362,249

(22) Filed: Jun. 29, 2021

(30) Foreign Application Priority Data
Jul. 8, 2020 (KR) 10-2020-0083806

(51) Int. Cl. H01L 27/146

(52) U.S. Cl. CPC H01L 27/14634

(57) ABSTRACT

A 3D image sensor is disclosed. More particularly, an image sensor in which all constituents, including a photoelectric conversion element and constituents for image data output, are in a three-dimensional stack, thereby improving the degree of integration and freedom of a corresponding layout, and resolving the difference in time response when reading pixel data for each row.

### CROSS REFERENCE TO RELATED APPLICATION

The present application claims priority to Korean Patent Application No. 10-2020-0083806, filed Jul. 8, 2020, the entire contents of which are incorporated herein for all purposes by this reference.

### BACKGROUND OF THE INVENTION

### Field of the Invention

The present invention relates to a 3D image sensor. More particularly, the present invention relates to an image sensor in which all constituents including a photoelectric conversion element and constituents for image data output are in a three dimensional stack, thereby improving the degree of integration and the freedom of a corresponding layout, and resolving the difference in time response when reading data from each row of pixels.

### Description of the Related Art

An image sensor is an image pickup device that generates an image in a mobile phone camera and the like. Image sensors may be classified into charge-coupled device (CCD) image sensors and complementary metal-oxide-semiconductor (CMOS) image sensors, according to the manufacturing process and application method. With a general semiconductor chip manufacturing process, CMOS image sensors have been widely used due to excellent integration competitiveness and economic efficiency, and ease of connection with nearby chips.

The image sensor maintains an appropriate exposure by a shutter operation that adjusts the amount of light with the start and the end of light exposure. The shutters adjusting the amount of light may be classified as rolling shutters and global shutters, depending on their method of operation.

In the rolling shutter method, signals photoelectrically converted by optical elements (for example, photodiodes) of each row in one frame are transmitted sequentially or row-by-row to floating diffusion region in a selected row, and an image signal of the corresponding pixels is subsequently output.

In contrast, in the global shutter method, all signals photoelectrically converted by all optical elements in one frame are transmitted to the corresponding floating diffusion regions simultaneously, and an image signal of the corresponding pixels is output from sequentially selected rows.

FIG. 1 is a diagram showing a configuration of a conventional image sensor.

Hereinafter, with reference to the figure, a schematic structure of a conventional image sensor using a rolling shutter method and its problems will be described.

Referring to FIG. 1, in a conventional image sensor 9, unit pixels 911 are in a two-dimensional (2D) array, and unit pixels 911 in the same column within a pixel area 910 share a common column lead-out line for transmitting analog signals including image signals. In addition, an ADC block 930 includes multiple ADCs 931, 933, and 935 corresponding to the respective columns. Each of the ADCs 931, 933, and 935 receives analog image signals of the unit pixels 911 transmitted through the connected lead-out line, and converts the analog image signals to digital signals.

Herein, the ADC block 930 has the ADCs in a line array, so that each ADC 931, 933, or 935 inevitably converts signals from all of the unit pixels 911 in a corresponding column. Because of this, when a defect occurs in the individual ADC 931, 933, or 935, a line-shaped image defect may result.

In addition, in the rolling shutter method, all the pixel data are not read simultaneously, but are read on a row-by-row basis. Because of this, there is a difference in the timing of reading data of each row. When pixel data is read sequentially on a row-by-row basis, a “Jello” effect occurs, in which an image of a moving object blurs, or the object looks bent. In order to solve the “Jello” effect, the difference in row-by-row reading time needs to be reduced by reading the pixel data for each row as fast as possible, but there is a limit to row reading speed in the conventional structure.

The foregoing is intended merely to aid in the understanding of the background of the present invention, and is not intended to mean that the present invention falls within the purview of information that is already known to those skilled in the art.

Document of Related Art

(Patent Document 1) Korean Patent No. 10-0819746, “a 3D structure laminated solid-state image sensor, and a method for manufacturing the same)”

### SUMMARY OF THE INVENTION

The present invention solves the problems in the related art described above using a stacked image sensor having an improved structure.

The present invention provides a 3D image sensor in which all structures, including a photoelectric conversion element and structures for image output, are in a 3D stacked structure so as to improve image processing speed.

In addition, the present invention provides a 3D image sensor that resolves the difference in time response when reading pixel data for each row.

In addition, the present invention provides a 3D image sensor that improves the degree of integration and the freedom of a corresponding layout by constructing all the structures in a 3D stacked structure as described herein.

In addition, the present invention provides a 3D image sensor, wherein the individual ADCs and the individual unit pixels correspond in a 1:1 relationship, so that when there is a defect in one of the ADCs, only a spot-shaped image defect can occur, rather than a line-shaped image defect, thereby facilitating easy correction through by image signal processing (ISP).

The present invention may be implemented by one or more embodiments having the following configured to achieve the above-described objectives.

According to one or more embodiments of the present invention, there is provided a 3D image sensor including: a first semiconductor chip including unit pixels in a two-dimensional (2D) array; a second semiconductor chip on the first semiconductor chip, and electrically connected to the first semiconductor chip; and a third semiconductor chip on the second semiconductor chip, and electrically connected to the second semiconductor chip, wherein the first, second and third semiconductor chips are in a stack, the first semiconductor chip includes a first substrate having a pixel area, the unit pixels are in a 2D array on and/or in the first substrate in the pixel area, and each unit pixel includes a photoelectric conversion element; the second semiconductor chip includes a second substrate having a driving element area and a plurality of driving elements in a 2D array on and/or in the second substrate in the driving element area; and the third semiconductor chip includes a third substrate having a logic area and a plurality of analog-digital converters (ADCs) in a 2D array on and/or in the third substrate in the logic area.

According to a further embodiment of the present invention, in the 3D image sensor, the pixel area, the driving element area, and the logic area may overlap in a z-axis or chip stacking direction.

According to a still further embodiment of the present invention, in the 3D image sensor, each of the ADCs may correspond with a respective one of the unit pixels in a 1:1 relationship.

According to other or further embodiments of the present invention, the 3D image sensor may further include a fourth semiconductor chip on the third semiconductor chip and in the stack, and electrically connected to the third semiconductor chip, wherein the fourth semiconductor chip may include a fourth substrate having a memory area and a plurality of memory cells in a 2D array on the fourth substrate in the memory area.

According to a still further embodiment of the present invention, in the 3D image sensor, the memory area may overlap the logic area in the z-axis or chip stacking direction.

According to another or further embodiment of the present invention, in the 3D image sensor, each of the memory cells may correspond with respective ones of the unit pixels and of the ADCs in a 1:1:1 relationship.

According to one or more other embodiments of the present invention, there is provided a 3D image sensor including a first semiconductor chip including unit pixels in a 2D array in a pixel area; a second semiconductor chip including driving elements in a 2D array in a driving element area, the second semiconductor chip being on the first semiconductor chip; and a third semiconductor chip including a plurality of ADCs in a 2D array in a logic area, the third semiconductor chip being on the second semiconductor chip, wherein the first, second and third semiconductor chips are in a stack, and each of the unit pixels and respective ones of the ADCs correspond in a 1:1 relationship in a z-axis or chip stacking direction.

According to one or more further embodiments of the present invention, the 3D image sensor may further include: a fourth semiconductor chip including a plurality of memory cells in a 2D array in a memory area, the fourth semiconductor chip being on the third semiconductor chip and in the stack, wherein each of the memory cells of the fourth semiconductor chip and each of the ADCs may correspond in a 1:1 relationship in the z-axis or chip stacking direction.

According to a still further embodiment of the present invention, in the 3D image sensor, each of the first, second, third and fourth semiconductor chips may be electrically connected to an adjacent chip.

According to one or more further embodiments of the present invention, in the 3D image sensor, the unit pixel may include a photoelectric conversion element; a transfer transistor connecting and disconnecting the photoelectric conversion element and a floating diffusion region so as to transmit electric charges from the photoelectric conversion element (e.g., to the floating diffusion region); and the floating diffusion region, storing the electric charges from the photoelectric conversion element.

According to still further embodiments of the present invention, in the 3D image sensor, the photoelectric conversion element, the transfer transistor, and the floating diffusion region in each of the unit pixels may correspond in a 1:1:1 relationship.

According to still further embodiments of the present invention, in the 3D image sensor, the driving element may include a reset transistor configured to reset a voltage of the floating diffusion region to a power supply voltage; and a selection transistor configured to amplify the voltage of the floating diffusion region, wherein each of the reset transistor and the selection transistor may correspond with the photoelectric conversion element in a 1:1 relationship.

According to one or more other embodiments of the present invention, there is provided a 3D image sensor including a first semiconductor chip including unit pixels in a 2D array in a pixel area; a second semiconductor chip including unit driving elements in a 2D array in a driving element area overlapping the pixel area and corresponding with the unit pixels in a 1:1 relationship, the second semiconductor chip being on the first semiconductor chip; and a third semiconductor chip including a plurality of ADCs in a 2D array in a logic area overlapping the pixel area, corresponding with the individual unit pixels in a 1:1 relationship, the third semiconductor chip being on the second semiconductor chip, wherein the first, second and third semiconductor chips are in a stack.

According to one or more further embodiments of the present invention, the 3D image sensor may further include a fourth semiconductor chip including a plurality of memory cells in a 2D array in a memory area, the fourth semiconductor chip being on the third semiconductor chip and in the stack, wherein the memory cells and the ADCs may correspond in a 1:1 relationship.

According to the above configurations, the present invention has the following effects.

According to the present invention, all structures, including a photoelectric conversion element and structures for image output, are in a 3D stacked structure, thereby improving image processing speed.

In addition, the present invention resolves the difference in time response when reading pixel data for each row.

In addition, the present invention improves the degree of integration and the freedom of a corresponding layout by constructing all of the structures in a 3D stacked structure as described above.

In addition, according to the present invention, the individual ADC and each unit pixel are stacked and correspond in a 1:1 relationship, so that a defect in an ADC results in only a spot-shaped image defect, rather than a line-shaped image defect, thereby facilitating easy correction ISP.

Meanwhile, effects described in the present specification and potential effects thereof that are expected by the technical features of the present invention are considered as effects described in the present specification, even though these effects may not be clearly mentioned herein.

### BRIEF DESCRIPTION OF THE DRAWINGS

The above and other objectives, features, and other advantages of the present invention will be more clearly understood from the following detailed description when taken in conjunction with the accompanying drawings, in which:

FIG. 1 is a diagram showing a configuration of a conventional image sensor;

FIG. 2 is an exploded perspective view showing a 3D image sensor according to one or more embodiments of the present invention;

FIG. 3 is a perspective view showing the 3D image sensor of FIG. 2 for reference;

FIG. 4 is a schematic plan view showing a first semiconductor chip of the image sensor of FIG. 2;

FIG. 5 is a schematic plan view showing a second semiconductor chip of the image sensor of FIG. 2;

FIG. 6 is a schematic plan view showing a third semiconductor chip of the image sensor of FIG. 2; and

FIG. 7 is a schematic plan view showing a fourth semiconductor chip of the image sensor FIG. 2.

### DETAILED DESCRIPTION OF THE INVENTION

It is noted that embodiments of the present invention may be changed to a variety of similar or other embodiments. The scope of the present invention should not be interpreted as being limited to the embodiments described hereinbelow, but should be interpreted on the basis of the descriptions in the appended claims. In addition, various embodiments of the present invention are provided for reference in order to fully describe the invention for those skilled in the art.

In the following specification, when one element is referred to as being placed or positioned “on”, “above”, “at an upper side of”, or “at an upper portion of” another element, the first element may be in contact with the upper surface of the second element, or spaced apart from the second element by a predetermined distance. In addition, when one element is spaced apart from another element, there may be one or more third elements therebetween. Further, when one element is “directly placed on another element”, or “directly above”, there is no intervening elements between the two elements.

The terms “first”, “second”, etc. may be used to describe various items, such as various elements, regions, and/or parts, but the items are not limited by the terms, and it is noted that a second element is not a first element.

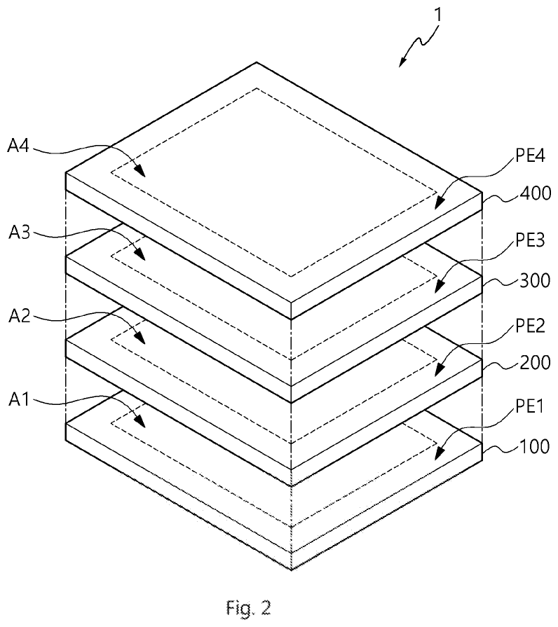

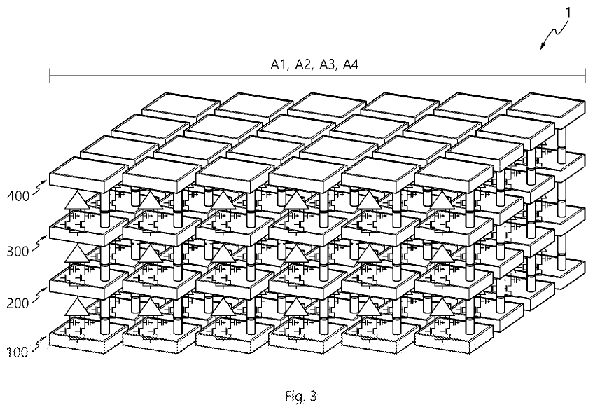

FIG. 2 is an exploded perspective view showing a 3D image sensor according to one or more embodiments of the present invention. FIG. 3 is a perspective view showing the 3D image sensor of FIG. 2 for reference.

Hereinafter, a 3D image sensor according to embodiments of the present invention will be described in detail with reference to the accompanying drawings.

Referring to FIGS. 2 and 3, the present invention relates to a 3D image sensor 1. More particularly, the present invention relates to an image sensor 1 in which all constituents, including a photoelectric conversion element and constituents for image data output, are stacked in three dimensions, thereby improving the degree of integration and the freedom of a corresponding layout, and resolving the difference in time response when reading pixel data for each row.

In addition, as will be described below in detail, in the 3D image sensor 1 according to embodiments of the present invention, analog-to-digital converters (ADC) in a 2D array (e.g., an area type), not a line type as in the related art. Thus, each unit pixel and each ADC correspond in a 1:1 relationship. Therefore, when a defect occurs in an ADC, only a spot-shaped image defect results, rather than a line-shaped image defect. Accordingly, relatively easy correction is possible.

According to one or more embodiments of the present invention, the 3D image sensor 1 may have a stack structure, including a second semiconductor chip 200 on a first semiconductor chip 100, a third semiconductor chip 300 on the second semiconductor chip 200, and a fourth semiconductor chip 400 on the third semiconductor chip 300. That is, the first to fourth semiconductor chips 100, 200, 300, and 400 are stacked or overlaid in a vertical direction (i.e., a z-axis direction), so that surfaces of the largest area face one another. Bonding between the stacked chips may be performed at a wafer level.

Bonding between individual semiconductor chips may be performed using metal-to-metal bonding, but no limitation thereto is imposed. For example, it is preferable that electrical connections between each of the semiconductor chips include Cu—Cu bonding. It is more preferable that the electrical connections are made by Cu—Cu hybrid bonding.

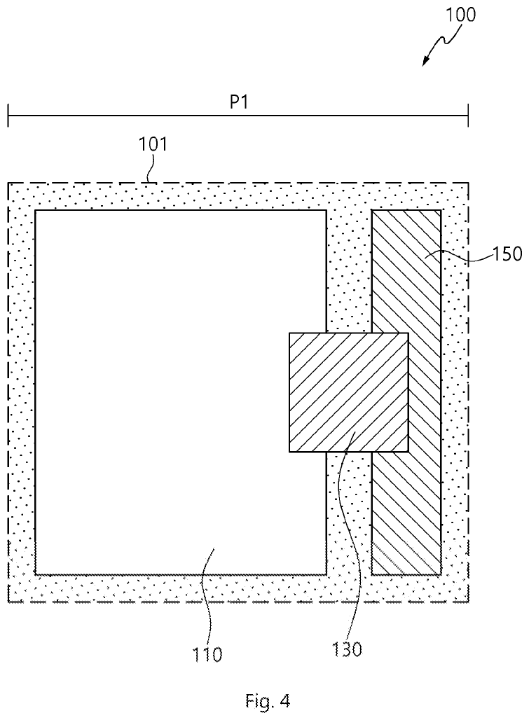

FIG. 4 is a schematic plan view showing a first semiconductor chip of the image sensor of FIG. 2.

Referring to FIGS. 2 to 4 for a detailed description, in a pixel area A1 of the first semiconductor chip 100 that forms the bottom or base layer or chip of the 3D image sensor 1, a plurality of unit pixels Plare on a first substrate 101 in a 2D array, along x-axis and y-axis directions (e.g., in rows and columns). Each individual unit pixel P1 includes a photoelectric conversion element 110 generating an electron-hole pair when sensing light (e.g., of a certain wavelength or wavelength band); a transfer transistor 130 connecting or disconnecting the photoelectric conversion element 110 and a floating diffusion region 150 so as to transmit the electric charges in the photoelectric conversion element 110 when connected; and the floating diffusion region 150 storing the electric charges from the photoelectric conversion element 110. It is preferable that the photoelectric conversion element 110, the transfer transistor 130, and the floating diffusion region 150 are in a 1:1:1 relationship.

That is, in the image sensor 1, a plurality of photoelectric conversion elements 110 do not share a single transfer transistor 130 and floating diffusion region 150 in common. In addition, the first substrate 101 may be on the lowermost surface of the first semiconductor chip 100, as shown in the figures. The pixel area A1 may be surrounded by a pixel-surrounding area PE1 and may be positioned in the central portion of the first semiconductor chip 100 (see FIG. 2), but no limitation thereto is imposed.

Describing the unit pixel P1 formed in the pixel area A1 in more detail, for example, the transfer transistor 130 may be on or over the photoelectric conversion element 110, and the floating diffusion region 150 may be near the photoelectric conversion element 110, but on an opposite side of the transfer transistor 130 from the photoelectric conversion element 110. In addition, the individual unit pixels P1s may have the same structure as each other, but no limitation thereto is imposed. In addition, on the first substrate 101, a plurality of interlayer insulation films (not shown) and metal wiring layers (not shown) may be included for electrical connection to the second substrate 201.

The metal wiring layer comprises, for example, a single metal or an alloy film of two or more types of metal. In some cases, the metal wiring layer may comprise a plurality of different conductive layers, and each conductive layer may be a single metal or an alloy. The interlayer insulation film comprises, for example, an insulation material such as silicon dioxide, which may be doped (e.g., with fluorine or boron and/or phosphorus) or undoped. According to an embodiment of the present invention, the 3D image sensor 1 is, for example, a backside-illuminated image sensor. With the first substrate 101 in the center, a color filter and a micro lens (not shown) may be formed on the surface opposite from the metal wiring layer.

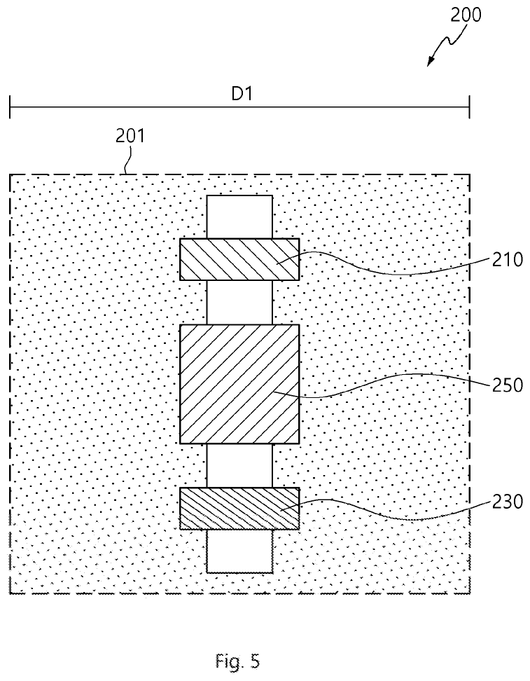

FIG. 5 is a schematic plan view showing a second semiconductor chip of the image sensor of FIG. 2.

Referring to FIGS. 2, 3, and 5, the second semiconductor chip 200 is on the first semiconductor chip 100. A plurality of interlayer insulation films and metal wiring layers (not shown) may be above or below the second substrate 201 (e.g., between the second semiconductor chip 200 and the third semiconductor chip 300, or between the second semiconductor chip 200 and the first semiconductor chip 100). On the second substrate 201, driving elements such as a plurality of reset transistors 210, selection transistors 230, source followers 250, and the like may be in a 2D array. Each reset transistor 210, each selection transistor 230, and each source follower 250 may be in a driving element area A2 of the second semiconductor chip 200, and may correspond with the photoelectric conversion element 110 of each unit pixel P1 in a 1:1 relationship. The driving element area A2 may be surrounded by a driving-element-surrounding area PE2, and may be in the central portion of the second semiconductor chip 200. In addition, the driving element area A2 may overlap the pixel area A1 in the z-axis or chip stacking direction. Hereinafter, the area including one reset transistor 210, one selection transistor 230, and one source follower 250 and corresponding to the unit pixel P1 is referred to as a unit driving element D1.

That is, a plurality of unit pixels P1 or photoelectric conversion elements 110 do not share a common reset transistor 210, selection transistor 230, and source follower 250. The reset transistor 210 is a constituent that resets the electric charges stored in the floating diffusion region 150, by resetting the voltage of the floating diffusion region 150 to a power supply voltage. Thus, a via, contact or other metal connection from a power supply node or wire (not shown) may be in ohmic contact with the node in the driving element D1 between the reset transistor 210 and the source follower 250. The selection transistor 230 is a constituent that amplifies the voltage of the floating diffusion region 150 (e.g., when selected). The source follower 250 is a constituent that selectively outputs the amplified voltage according to a selection signal (e.g., transmitted to the selection transistor 230 to turn it on). On the second substrate 210, a plurality of interlayer insulation films and metal wiring layers may be included for electrical connection with a third substrate 301, and a detailed description thereof will be omitted.

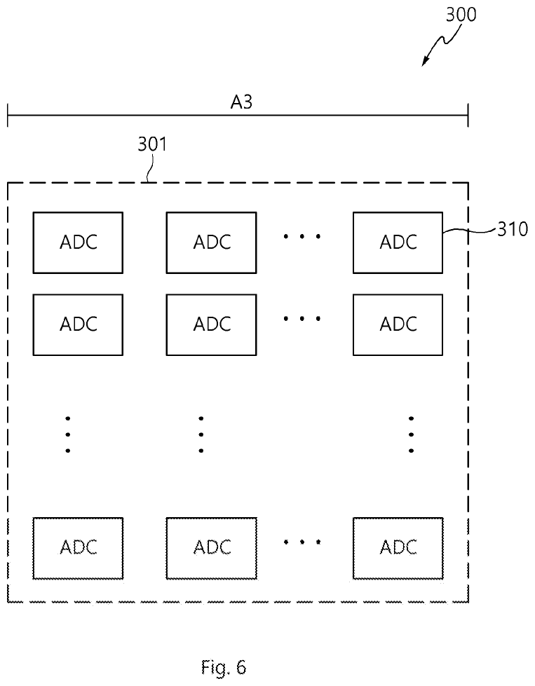

FIG. 6 is a schematic plan view showing a third semiconductor chip of the image sensor of FIG. 2.

Referring to FIGS. 2, 3, and 6, the third semiconductor chip 300 is placed on the second semiconductor chip 200. A plurality of logic elements are on the third substrate 301 of the third semiconductor chip 300. For example, the logic elements may be on the third substrate 301 along or in a logic area A3. The logic area A3 may overlap the pixel area A1 and the driving element area A2 in the z-axis or chip stacking direction, and may be surrounded by a logic-surrounding area PE3. In the logic area A3, the plurality of logic elements are in a 2D array. For example, the logic element may be on a lowermost surface of the third substrate 301 (i.e., facing the second semiconductor chip 200). In addition, transistors of the logic elements may be on the third substrate 301.

Each of the logic elements includes various circuits for processing a pixel signal from the unit pixel P1, such as, for example, analog-to-digital converters (ADCs) 310. The ADCs 310 are in a 2D array on the third substrate 301, facing the unit pixels P1. The ADCs 310 are not arranged in such a manner that a single ADC 310 corresponds with a plurality of unit pixels P1. Each ADC 310 corresponds with an individual unit pixel P1 in a 1:1 relationship.

Hereinafter, the configuration of the conventional image sensor 9 and its problems will be described again.

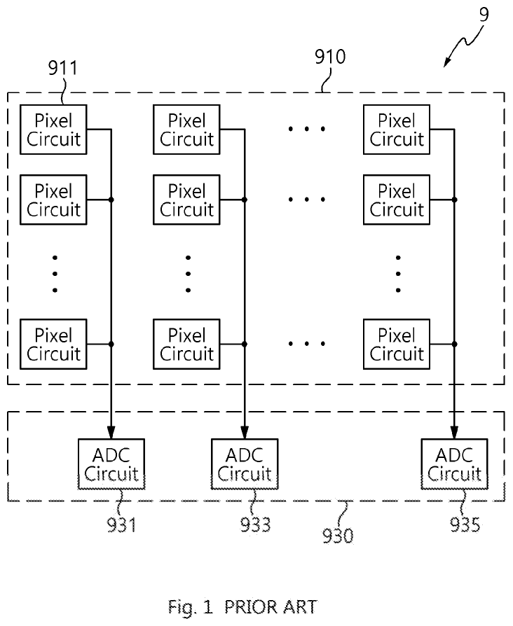

Referring to FIG. 1, in the conventional image sensor 9, the unit pixels 911 are arranged in a 2D structure, and the unit pixels 911 in the same column share a common column lead-out line for transmitting analog image signals. In addition, an ADC block 930 includes a plurality of ADCs 931, 933, and 935 corresponding to the respective columns. Each of the ADCs 931, 933, and 935 receives the analog image signals of the corresponding column of unit pixels 910 transmitted on the lead-out line, and converts the analog image signals to digital signals.

Herein, the ADC block 930 has the ADCs in a line array, so that each ADC 931, 933, or 935 operates of all of the unit pixels 910 in an individual column. Because of this, when a defect occurs in the individual ADC 931, 933, or 935, a line-shaped image defect may occur.

In addition, in the rolling shutter method, data from all of the pixels are not read simultaneously, but are read on a row-by-row basis. Because of this, there is a difference in the timing of reading the data from each row. When pixel data is read sequentially on a row-by-row basis, the “Jello” effect occurs, in which an image of a moving object blurs, or the object looks bent. In order to solve the “Jello” effect, the difference in time may be reduced by reading the pixel data for each row as fast as possible. However, there is a limit in the conventional structure.

In order to solve such problems, referring to FIGS. 2, 3, and 6, in the 3D image sensor 1 according to embodiments of the present invention, the ADC 310 and the unit pixel P1 are not arranged in two dimensions (e.g., side-by-side, with components thereof in a common layout), but are stacked or overlapping (e.g., in a 3D structure). Specifically, an individual ADC 310 and an individual unit pixel P1 are stacked or overlapping in a third dimension (where the layouts of the ADC 310 and the unit pixel P1 are essentially in two other dimensions), and correspond in a 1:1 relationship, so that when a defect occurs in the ADC 310, only a spot-shaped defect may occur, rather than a line-shaped defect. The spot-shaped defect may be easily corrected by ISP.

That is, when the ADCs 310, the pixel area A1, and the driving element area A2 are in a 3D stack, if one ADC 310 corresponds with a plurality of unit pixels P1, the above-described problems occurring in the conventional image sensor 9 inevitably occur. Therefore, in the image sensor 1 according to one or more embodiments of the present invention, the individual ADC 310 and each unit pixel P1 are in a 1:1 relationship, thereby preventing the above-described problems from occurring. More specifically, each ADC 310 corresponds with an individual photoelectric conversion element 110 in a 1:1 relationship.

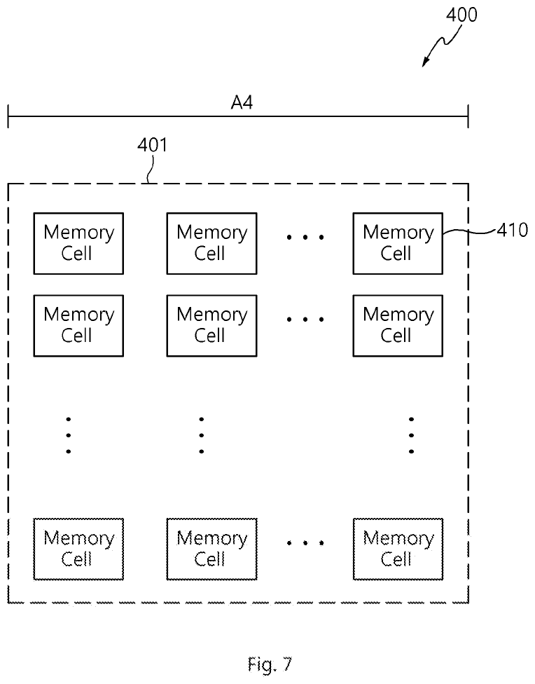

FIG. 7 is a schematic plan view showing a fourth semiconductor chip of the image sensor in FIG. 2.

Referring to FIGS. 2, 3, and 7, the fourth semiconductor chip 400 is on the third semiconductor chip 300 (e.g., in the stack). A plurality of memory cells 410 may be on a fourth substrate 401 of the fourth semiconductor chip 400. The memory cells 410 are in a 2D array within a memory area A4. A memory-surrounding area PE4 is around or surrounds the memory area A4.

For example, the memory cells 410 may be on a lowermost surface of the fourth substrate 401 (i.e., facing the third semiconductor chip 300). Transistors for the memory cells 410 may be on the fourth substrate 401. The memory cells 410 may be used as an image buffer memory for storing frame images. It is preferable that an individual memory cell 410 corresponds with a unit pixel P1 and an ADC 310 in a 1:1:1 relationship.

Bonding between each of the first semiconductor chip 100 to the fourth semiconductor chip 400 may comprise metal-to-metal bonding as described above. In addition, with metal-to-metal hybrid bonding, electrical connections may comprise through-silicon vias (TSVs). In addition, electrical connections may comprise an integrated through via, but no limitation thereto is imposed.

As described above, the photoelectric conversion element 110, the ADC 310, and the memory cell 410 are in the z-axis or chip stacking direction in a 1:1:1 relationship, thereby improving the degree of integration and data processing speed, and preventing a line-shaped image defect.

The foregoing detailed description illustrates the present invention. In addition, the foregoing illustrates and describes preferred embodiments of the present invention, and the present invention may be utilized in various other combinations, modifications, and environments. That is, it is possible to make changes or modifications within the scope of the concept of the invention disclosed herein, within the scope of equivalents to the above-described disclosure, and/or within the skill and knowledge of those skilled in the art. The above-described embodiments are intended to describe the best mode for carrying out the technical spirit of the present invention, and various modifications for specific applications and uses of the present invention are possible. Accordingly, the foregoing detailed description is not intended to limit the present invention to the embodiments disclosed.

What is claimed is:

1. A 3D image sensor comprising:
a first semiconductor chip including unit pixels in a two-dimensional (2D) array;
a second semiconductor chip on the first semiconductor chip, and electrically connected to the first semiconductor chip; and
a third semiconductor chip on the second semiconductor chip, and electrically connected to the second semiconductor chip,
wherein the first, second and third semiconductor chips are in a stack,
the first semiconductor chip comprises a first substrate having a pixel area, a plurality of unit pixels in a 2D array on and/or in the first substrate in a pixel area, and each of the plurality of unit pixels includes a photoelectric conversion element,
the second semiconductor chip comprises a second substrate having a driving element area and a plurality of driving elements in a 2D array on and/or in the second substrate in the driving element area, and
the third semiconductor chip comprises a third substrate having a logic area and a plurality of analog-digital converters (ADCs) in a 2D structure on and/or in the third substrate in the logic area.

2. The 3D image sensor of claim 1, wherein the pixel area, the driving element area, and the logic area overlap in a z-axis or chip stacking direction.

3. The 3D image sensor of claim 1, wherein each of the ADCs corresponds with a respective one of the unit pixels in a 1:1 relationship.

4. The 3D image sensor of claim 3, further comprising:
a fourth semiconductor chip on the third semiconductor chip and in the stack, and electrically connected to the third semiconductor chip,
wherein the fourth semiconductor chip comprises a fourth substrate having a memory area and a plurality of memory cells in a 2D array on the fourth substrate in the memory area.

5. The 3D image sensor of claim 4, wherein the memory area overlaps the logic area in a z-axis or chip stacking direction.

6. The 3D image sensor of claim 4, wherein each of the plurality of memory cells corresponds with respective ones of the plurality of unit pixels and of the plurality of ADCs in a 1:1:1 relationship.

7. A 3D image sensor comprising:
a first semiconductor chip including unit pixels in a two-dimensional (2D) array in a pixel area;
a second semiconductor chip including driving elements in a 2D array in a driving element area, the second semiconductor chip being on the first semiconductor chip; and
a third semiconductor chip including a plurality of ADCs in a 2D array in a logic area, the third semiconductor chip being on the second semiconductor chip,
wherein the first, second and third semiconductor chips are in a stack, and
each of the plurality of unit pixels and respective ones of the plurality of ADCs correspond in a 1:1 relationship in a z-axis or chip stacking direction.

8. The 3D image sensor of claim 7, further comprising:
a fourth semiconductor chip including a plurality of memory cells in a 2D array in a memory area, the fourth semiconductor chip being on the third semiconductor chip and in the stack,
wherein each of the memory cells of the fourth semiconductor chip and a respective one of the plurality of ADCs correspond in a 1:1 relationship in the z-axis or chip stacking direction.

9. The 3D image sensor of claim 8, wherein each of the first semiconductor chip, the second semiconductor chip, the third semiconductor chip, and the fourth semiconductor chip are electrically connected to an adjacent chip.

10. The 3D image sensor of claim 7, wherein the unit pixel comprises:
a photoelectric conversion element;
a transfer transistor connecting and disconnecting the photoelectric conversion element and a floating diffusion region to transmit electric charges from the photoelectric conversion element; and
the floating diffusion region, storing the electric charges from the photoelectric conversion element.

11. The 3D image sensor of claim 10, wherein the photoelectric conversion element, the transfer transistor, and the floating diffusion region in each of the unit pixels correspond in a 1:1:1 relationship.

12. The 3D image sensor of claim 10, wherein the driving element comprises:
a reset transistor configured to reset a voltage of the floating diffusion region to a power supply voltage; and
a selection transistor configured to amplify the voltage of the floating diffusion region,
wherein the reset transistor and the selection transistor correspond with the photoelectric conversion element in a 1:1 relationship.

13. A 3D image sensor comprising:
a first semiconductor chip including unit pixels in a two-dimensional (2D) array in a pixel area;
a second semiconductor chip including unit driving elements in a 2D array in a driving element area overlapping the pixel area, the unit driving elements corresponding with the unit pixels in a 1:1 relationship, the second semiconductor chip being on the first semiconductor chip; and
a third semiconductor chip including a plurality of analog-digital converters (ADCs) in a 2D array in a logic area overlapping the pixel area, the plurality of ADCs corresponding with the unit pixels in a 1:1 relationship, and the third semiconductor chip being on the second semiconductor chip;
wherein the first, second and third semiconductor chips are in a stack.

14. The 3D image sensor of claim 13, further comprising:
a fourth semiconductor chip including a plurality of memory cells in a 2D array in a memory area, the fourth semiconductor chip being on the third semiconductor chip and in the stack,
wherein each of the memory cells and respective ones of the plurality of ADCs correspond in a 1:1 relationship.

15. The 3D image sensor of claim 14, wherein the memory area overlaps the logic area in a z-axis or chip stacking direction.

16. The 3D image sensor of claim 13, wherein the pixel area, the driving element area, and the logic area overlap in a z-axis or chip stacking direction.

17. The 3D image sensor of claim 13, wherein the second semiconductor chip is electrically connected to the first semiconductor chip, and the third semiconductor chip is electrically connected to the second semiconductor chip.

18. The 3D image sensor of claim 14, wherein the second semiconductor chip is electrically connected to the first semiconductor chip, and the third semiconductor chip is electrically connected to the second semiconductor chip, and the fourth semiconductor chip is electrically connected to the third semiconductor chip.
